(19) United States
(12) Patent Application Publication
(10) Pub. No.: US 2007/0226553 A1
(43) Pub. Date: Sep. 27, 2007

(54) Multiple banks read and data compression for back end test

(76) Inventors: Khaled Fekih-Romdhane, Houston, TX (US); Phat Truong, Houston, TX (US)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/385,539

(22) Filed: Mar. 21, 2006

(51) Int. Cl. G11C 29/00

(52) U.S. Cl. 714/718

(57) ABSTRACT

Methods and apparatus that may be used to increase back-end testing throughput by allowing simultaneous access to multiple banks are provided. Techniques described herein take advantage of the compression that may be achieved in back-end testing, particularly when only an indication of whether a device has passed or failed is required and no indication of a particular location of a failure is necessary.

### CROSS-REFERENCE TO RELATED APPLICATIONS

This application is related to U.S. patent application Ser. No. ______, Attorney Docket No. INFN/0242, entitled “PARALLEL READ FOR FRONT END COMPRESSION MODE,” filed on the same day as the present application and herein incorporated by reference in its entirety.

### BACKGROUND OF THE INVENTION

1. Field of the Invention

The invention generally relates to semiconductor testing and, more particularly, to testing dynamic random access memory (DRAM) devices.

2. Description of the Related Art

The evolution of sub-micron CMOS technology has resulted in an increasing demand for high-speed semiconductor memory devices, such as dynamic random access memory (DRAM) devices, pseudo static random access memory (PSRAM) devices, and the like. Herein, such memory devices are collectively referred to as DRAM devices.

During the manufacturing process, multiple DRAM devices are typically fabricated on a single silicon wafer and undergo some form of testing (commonly referred to as wafer or “front-end” test) before the devices are separated and packaged individually. Such testing typically entails writing test data patterns to a particular series of address locations, reading data back from the same address locations, and comparing the data patterns read back to the data patterns written, in order to verify device operation. In conventional wafer testing, to avoid contention on data buses shared between multiple banks of DRAM memory cells, a single bank is accessed at a time. In a standard test mode, all lines of a shared bus may be used. During a single bank read access, a burst of data is read from the bank, for example, with multiple bits of data read at each clock edge.

In some cases, in an effort to reduce the amount of test data that must be passed between devices and a tester, the data read from the device arrays may be compressed. For example, for some DRAM architectures, 16 bits of data may be read in each access to the array at every clock edge. These 16 bits may be compressed internally to 4 bits, for example, by comparing four data bits stored at cells formed at an intersection of a word line (WL) and a column select line (CSL), with a test data pattern written to those bits, to generate a single “pass/fail” bit. Because repair algorithms typically replace entire wordlines and/or column select lines (depending on the particular repair algorithm) that have a failing cell with redundant wordlines and/or redundant column select lines, it is not necessary to know which particular cell or cells failed and, therefore, the single bit of data is sufficient.

Such repair algorithms are not typically used, however, in “back-end” tests performed after a device is separated from the wafer and packaged. Therefore, even greater compression may be achieved, for example, by combining the results of multiple test data pattern comparisons into a single bit. If this bit indicates a failure, an entire devices may be rejected as a failure. While such compression reduces the amount of test data that must be handled, having to access a single bank at a time limits the throughput of front-end testing.

Accordingly, what is needed is a mechanism for improving throughput of back-end testing.

### SUMMARY OF THE INVENTION

Embodiments of the present invention generally provide methods, apparatus, and systems for testing memory devices.

One embodiment provides a method of testing a memory device. The method generally comprises reading multiple bits (e.g., a burst) from multiple banks (e.g., 2 or more) of the memory device in parallel, generating, from the plurality of bits read from each bank, a reduced number of one or more compressed test data bits, combining the compressed test data bits from each bank to form a reduced number of one or more combined test data bits, routing the combined test data bits to one or more data lines shared between the multiple banks, and providing the combined test data bits as output on one or more data pins of the memory device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a dynamic random access memory (DRAM) device in accordance with embodiments of the present invention;

FIG. 2 illustrates exemplary compression test logic in accordance with embodiments of the present invention;

FIG. 3 illustrates an exemplary DRAM data path circuitry in accordance with embodiments of the present invention;

FIGS. 4A and 4B illustrate the flow of data from different groups of banks using the exemplary data path circuitry of FIG. 3;

FIG. 5 is a flow diagram of exemplary operations for testing a DRAM device utilizing parallel reads of multiple banks, in accordance with embodiments of the present invention; and

FIG. 6 illustrates the flow of compressed data using the exemplary data path circuitry of FIG. 3.

### DETAILED DESCRIPTION OF THE PREFERRED EMBODIMENT

Embodiments of the invention generally provide methods and apparatus that may be used to increase back-end testing throughput by allowing simultaneous access to multiple banks. Techniques described herein take advantage of the compression that may be achieved in back-end testing, particularly when only an indication of whether a device has passed or failed is required and no indication of a particular location of a failure is necessary.

Embodiments of the present invention will be described herein with reference to an embodiment of a DRAM device utilizing parallel access two banks of memory cells, with each group having four banks. However, those skilled in the art will recognize that the concepts described herein may be applied, generally, to access a wide variety of arrangements having different numbers of bank groups and, additionally, different numbers of banks in each group.

Embodiments of the present invention will also be described herein with reference to compressing test data read from multiple banks into single bits of data and combining the single bits of data corresponding to multiple banks into a single “pass/fail” bit. However, those skilled in the art will recognize that test data corresponding to multiple banks of data may be compressed and combined and compressed in various ways utilizing various aspects of the present invention. Further, while embodiments of the present invention will be described herein with reference to back-end testing (involving a packaged device), those skilled in the art will recognize that the techniques described herein may also be applied at other stages of testing.

### An Exemplary Memory Device

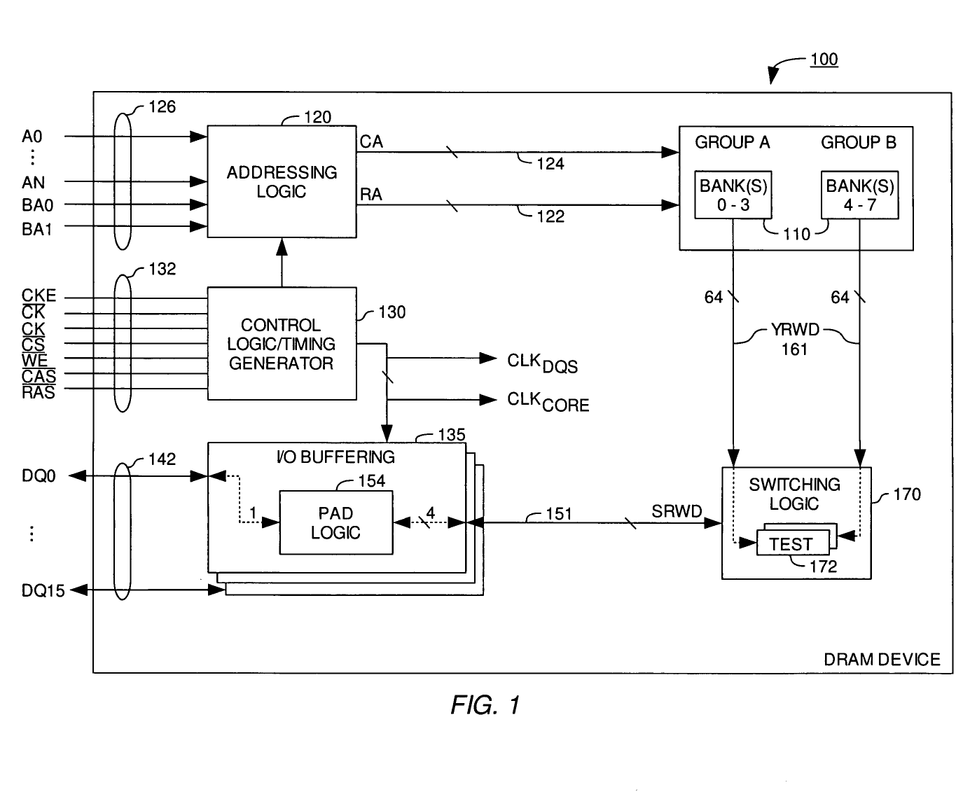

FIG. 1 illustrates an exemplary memory device 100 (e.g., a DRAM device) utilizing a data path logic design in accordance with one embodiment of the present invention, to access data stored in one or more memory arrays (or banks) 110. As illustrated, the banks 110 may be divided into groups that share a common set of data lines (YRWD lines), with four banks in each group (e.g., banks 0-3 are in Group A and banks 4-7 in Group B). As will be described in greater detail below, the throughput of back-end testing may be increased by utilizing parallel reads to banks in each group.

As illustrated, the device 100 may include control logic 130 to receive a set of control signals 132 to access (e.g., read, write, or refresh) data stored in the arrays 110 at locations specified by a set of address signals 126. The address signals 126 may be latched in response to signals 132 and converted into row address signals (RA) 122 and column address signals (CA) 124 used to access individual cells in the arrays 110 by addressing logic 120.

Data presented as data signals (DQ0-DQ15) 142 read from and written to the arrays 110 may be transferred between external data pads and the arrays 110 via I/O buffering logic 135. The I/O buffering logic 135 may be configured to achieve this transfer of data by performing a number of switching operations, for example, including assembling a number of sequentially received bits, and reordering those bits based on a type of access mode (e.g., interleaved or sequential, even/odd).

In general, during a write operation, the I/O buffering logic 135 is responsible for receiving data bits presented serially on external pads and presenting those data bits in parallel, possibly reordered depending on the particular access mode, on an internal bus of data lines referred to herein as spine read/write data (SRWD) lines 151. Assuming a total of 16 external data pads DQ<15:0>, there will be 64 total SRWD lines 151 (e.g., I/O buffering logic 135 performs a 4:1 fetch for each data pad) for a DDR-II device (32 for a DDR-I device and 128 for DDR-III).

As illustrated, the SRWD lines 151 may be connected to switching logic 170, which allows the SRWD lines 151 to be shared between the different groups of banks 110. As illustrated, each group of banks may have another set of data lines, illustratively shown as a set of data lines (YRWDL) 171 running in the vertical or “Y” direction. While each group may have a set of YRWD lines 171, the YRWD lines 171 for a group may be shared between banks 110 in that group. The switching logic 170 is generally configured to connect the read/write data lines (RWDL's) to the appropriate YRWD lines depending on the bank, or banks as the case may be, being accessed.

During a read access, the data propagates in the opposite direction through the switching logic 170 and I/O buffering logic 135 to the DQ lines. In other words, data may be transferred from the memory arrays 110 to the YRWD lines 161 and to the SRWD lines 151, via the switching logic 170, and from the SRWD lines 151 to the DQ pads, via the I/O buffering logic 135.

### Exemplary Test Logic

For some embodiments, test logic 172, may be included to reduce amount of test data transferred out of the DRAM device 100 during wafer testing. As illustrated, separate test logic 172 may be provided for each group of banks 110. While the test logic 172 is shown as being included in the switching logic 170, for some embodiments, the test logic 172 may be located elsewhere, for example, locally within the groups of banks 110.

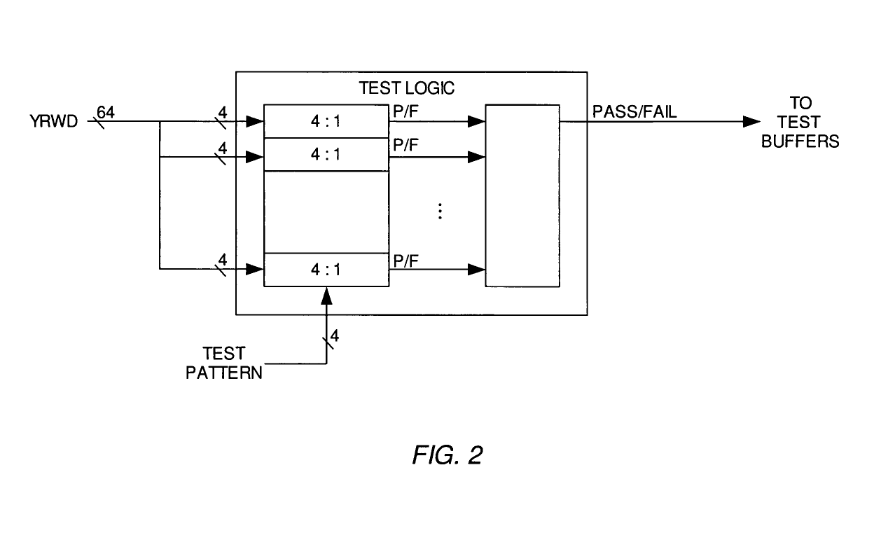

As illustrated in FIG. 2, for some embodiments test logic 172, may be configured to reduce (compress) the amount of test data by generating a single pass/fail signal from multiple bits of data read from a corresponding bank. In the illustrated example, the test logic 172 may generate intermediate pass/fail signals for each 4 bits of data read from the banks (e.g., 4 bits stored at a CSL-WL intersection). These intermediate pass/fail signals may indicate whether a corresponding 4 bits match a data pattern stored in a test register and that was written to corresponding locations in the bank. Assuming 64 bits of data are read from a bank at each access, the test logic 172 may compare data on YRWD lines to test data to generate 16 bits of compressed test data in the form of the intermediate pass/fail signals.

During front-end wafer tests, the compressed test data represented by the intermediate may be output to (test) buffers that provide access to the test data during wafer test. As described above, during front-end wafer tests, the intermediate pass/fail data may allow a particular location of failures to be identified, allowing for repair via replacement with redundant segments (e.g., wordlines or column select lines). However, during back-end testing (after packaging), replacement is not typically an option. Therefore, a single pass/fail bit indicative of the results of a comparison of the (64) bits of data read from the corresponding bank to previously defined data to previously defined data may be all that is necessary. In other words, if any of the comparisons fail, the single pass/fail bit may indicate a failure (e.g., zero).

As described above, separate test logic circuits 172 may be provided for each separate group of banks 110, with each test logic circuit 172 receiving, as input data on YRWD lines shared between the banks in the corresponding group. During back-end testing, each test logic circuit 172 may generate a single pass/fail bit indicating whether a failure is detected based on bits of data read from a corresponding bank. Because repair is not typically available during back-end testing, embodiments of the present invention may increase wafer test throughput by combining pass/fail bits generated (on separate lines) when accessing data from banks in different groups simultaneously and writing the combined test data (e.g., a single pass/fail bit representing multiple banks) out over normal SRWD data lines.

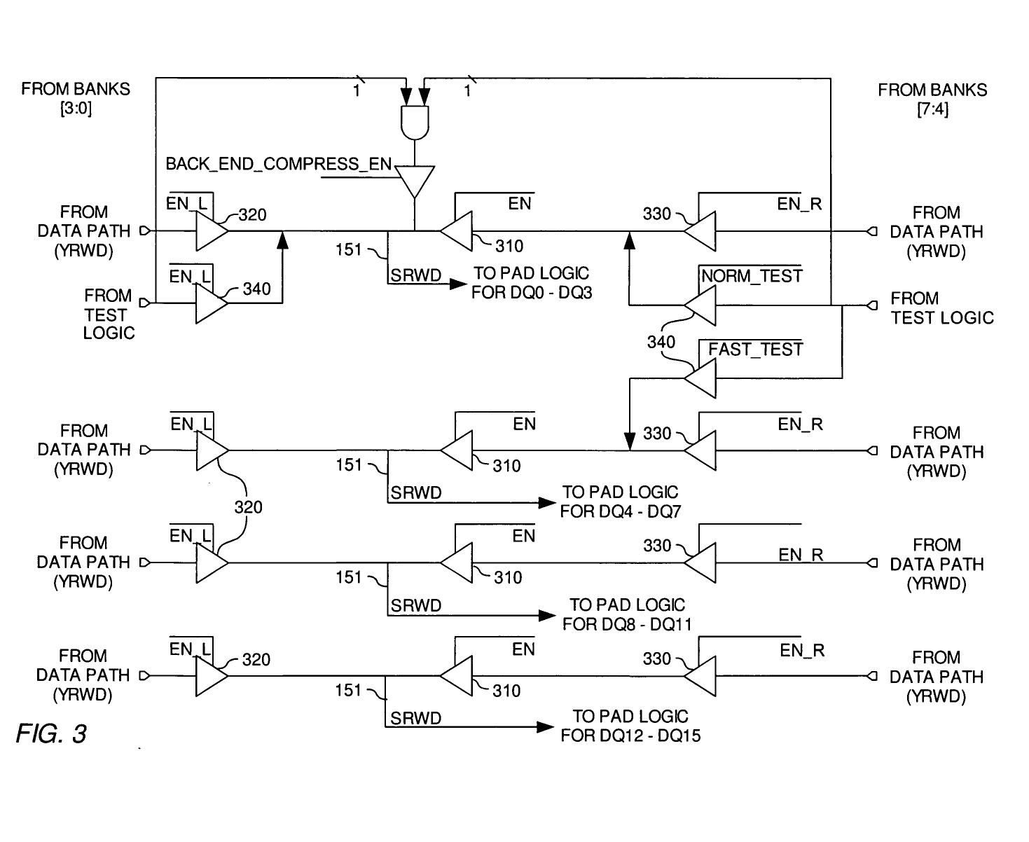

FIG. 3 illustrates data path circuitry that allows the combination of pass/fail bits, generated by test logic for different groups of DRAM banks, to be presented as a single combined bit on one of the SRWD lines 151. As illustrated, the data path circuitry includes a set of buffers 310, that allow the SRWD lines 151 to be shared between the groups of banks 110 without contention. The buffers 310 may be referred to as “center part” buffers, for example, because they may be centrally located and used to effectively isolate YRWD lines for group of banks physically located on different (e.g., left and right) sides of a DRAM device during normal (non-test) operation.

As illustrated, each 16 SRWD lines may be routed to pad logic for a corresponding four DQ pads. The pad logic for each DQ pad may, in turn, drive four bits of data out on successive edges of clock cycles. As an example, a first 16 SRWD lines may carry 16 bits of data to be driven out on a first four data pads DQ0-DQ3. On DQ0, the first four bits of data carried on the SRWD lines may be driven out, in sequence, for example, as Even1 (E1), Odd1 (O1), Even2 (E2) and Odd2 (O2) data bits on rising and falling edges of two successive clock cycles. The remaining bits of data may be driven out in a similar manner on other DQ pads.

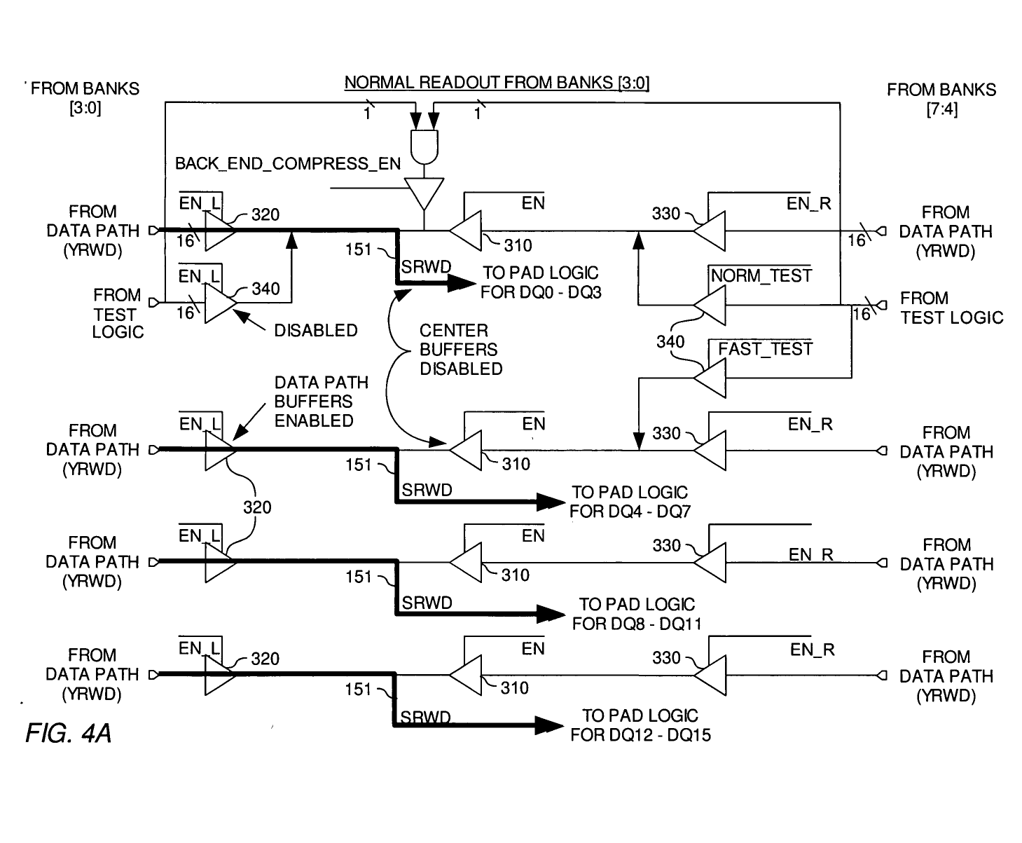

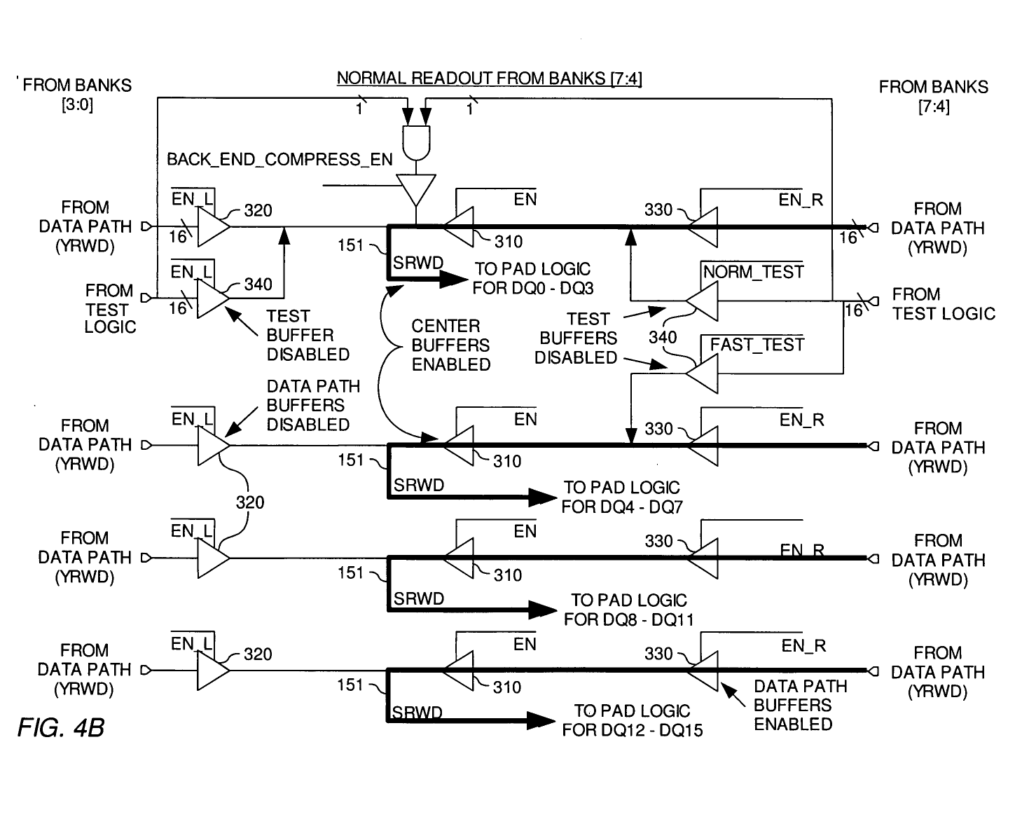

The function of the center part buffers 310 during normal operation is illustrated in FIGS. 4A and 4B, which show the flow of data during an access to a first group of banks (banks[3:0]) and a second group of banks (banks[7:4]), respectively. As illustrated in FIG. 4A, in order to access data from a bank in the first group, the center point buffers 310 may be disabled, while enabling a second set of “data path” buffers 320, thereby providing a data path from YRWD lines of the first group of banks to the SRWD lines.

As illustrated in FIG. 4B, in order to access data from a bank in the second group (banks[7:4]), the center point buffers 310 may be enabled along with a third set of data path buffers 330, while disabling the second set of “data path” buffers 320, thereby providing a data path from YRWD lines of the first group of banks to the SRWD lines.

A set of test data buffers 340 may be disabled to isolate test data lines from the SRWD lines during normal accesses to the banks 110 in either group. The test data buffers 340 may also be used to couple test data lines to the SRWD lines during test mode. During various (front-end) test modes, however, the test data buffers 340 may be enabled to drive test data (from test logic) onto the SRWD lines. In a normal front-end test mode (NORM_TEST asserted), a single bank at a time may be accessed and the test logic from a corresponding bank group may drive compressed test data onto a common set of SRWD lines to be read out. In a fast front-end test mode (FAST_TEST asserted), multiple banks may be accessed in parallel and the test logic for each corresponding bank group may drive compressed test data onto different sets of SRWD lines to be read out.

### Exemplary Back-End Testing With Parallel Bank Access

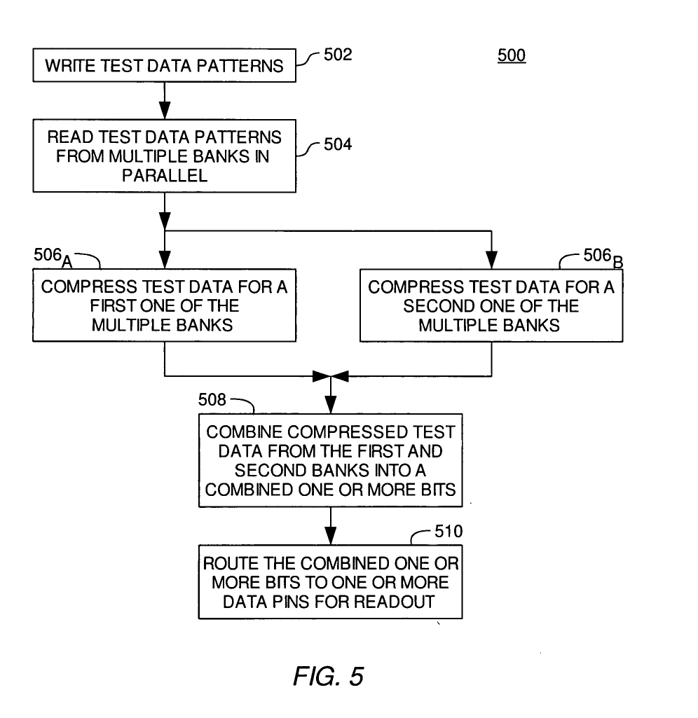

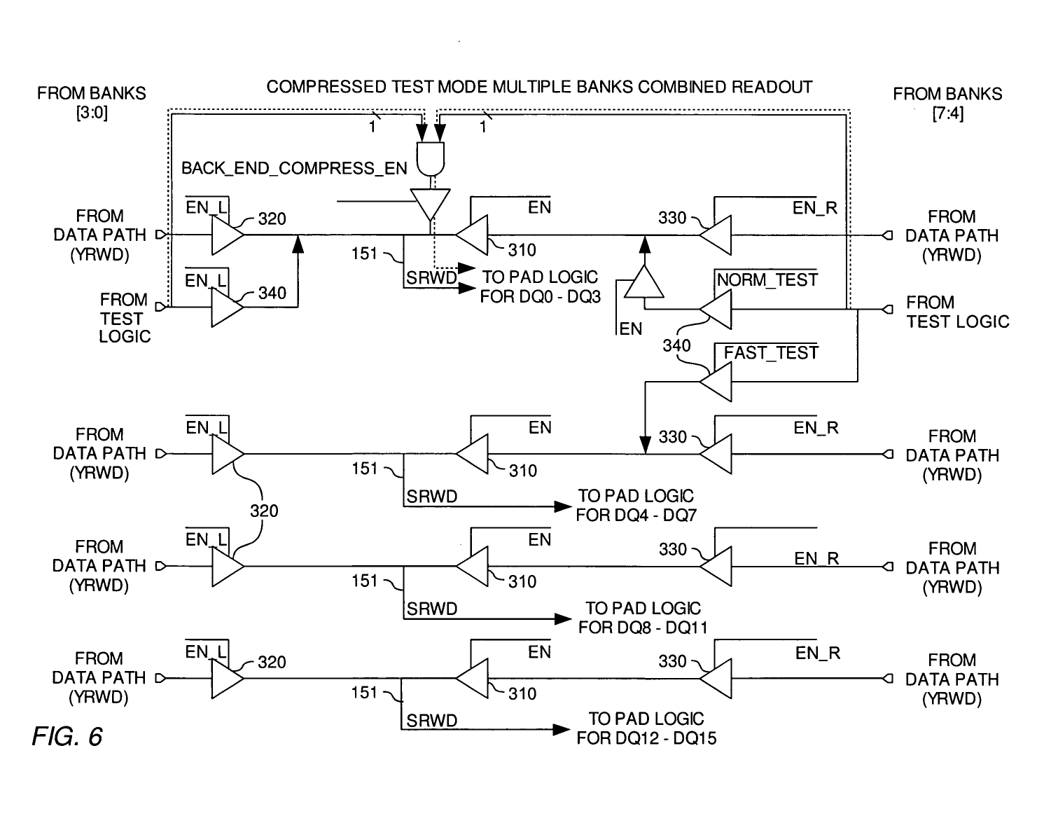

FIG. 5 is a flow diagram of exemplary operations 500 for back-end testing of a DRAM device utilizing parallel reads of multiple banks, in accordance with embodiments of the present invention. The operations 500 may be described with reference to FIG. 6, which illustrates the combining of compressed pass/fail bits from banks in different groups of banks using the exemplary data path circuitry described above.

The operations 500 begin, at step 502, by writing test data patterns. For some embodiments, the same test data pattern (possibly stored in an internal register) may be written to multiple locations in all banks. For example, as previously described, the same 4-bit test pattern may be written to four locations formed at each intersection between a column select line (CSL) and word line (WL).

At step 504, test data patterns may be read from multiple banks in parallel. The sharing of common data lines described thus far, generally forbids the simultaneous read of any 2 banks of memory during normal operations, to avoid data contention. As an example, a read from multiple banks within a group would result in data contention on shared YRWD lines, while a read from banks in different groups would result in data contention on SRWD lines.

However, simultaneous read from multiple banks is possible, by circumventing the SRWD data sharing and combining compressed test data generated from banks in different groups. At every read command during test, 2 banks (e.g., one in each group on different sides of the device) are accessed. For some embodiments, this may be achieved by modifying access logic so that, during such a test mode, Bank address bit 2 (BA[2]) is treated as a “don't care” bit. In other words, when a read command is issued to access bank 0, both bank 0 and bank 4 may be accessed to deliver a burst of data (on their respective YRWD lines). Similarly, when a read command is issued to access banks 1, 2, and 3, banks 1 and 5, 2 and 6, and 3 and 7 may be accessed, respectively.

At steps 506A and 506B, performed in parallel, test data for first and second of the multiple banks are compressed. For example, as previously described, the data on the YRWD lines for each group of banks may be compressed (e.g., 64:1 as described above) to generate a single pass/fail test bit corresponding to each bank. As previously described, the single pass/fail test bit may be generated from intermediate pass/fail signals indicating the results of comparisons of test data read from four bit locations formed at the intersection of a world line and column select line. For some embodiments, rather than a single pass/fail bit for each bank, multiple bits of compressed test data may be generated for each bank.

At steps 508, the compressed test data from the first and second banks are combined into a one or more combined test data bits. At step 510, the one or more combined test data bits are routed to one or more data pins to be read out.

As illustrated in FIG. 6, for some embodiments, a single pass/fail bit from separate bank groups may be combined into a single bit, which is routed to one of the data pins (e.g., DQ0). For example, single pass/fail bits from the test logic of different groups of banks may be combined (e.g., via a simple AND gate 350) into a single bit driven onto an SRWD line when a particular back-end test mode is enabled (COMB_TEST asserted). In this test mode, test data buffers 340 and normal data path buffers 320 may be disabled, thereby allowing the combined pass/fail bit to be driven out without contention. In this manner, assuming 64 bits of data are read from each bank, the test results from comparing 128 bits of data read from 2 banks may be consolidated and routed as a single bit read out on a single data pad.

By reading and testing data from multiple banks in parallel, back-end testing read sequences be performed in half the time when compared to conventional back-end testing modes, thereby significantly reducing overall back-end test times. For some embodiments, parallel reads of multiple banks may be enabled as a special back-end test mode and circuitry may also be included to allow for a “standard” back-end test mode with a single pass/fail compressed data from all banks driven onto different SRWD lines. For embodiments that include such circuitry, when the special (double rate) back-end test mode is enabled, buffers corresponding to the normal back-end test mode may be disabled (tristated) to avoid data contention. Similarly, when the normal back-end test mode is enabled, buffers corresponding to the double rate back-end test mode may be disabled. For some embodiment either or both test modes may be set, for example, via one or more bits set in a mode register via a mode register set command.

While the above description has reference to a particular embodiment having eight banks of DRAM cells, divided into two groups of four, those skilled in the art will recognize that this embodiment is exemplary only and the techniques described herein may be applied to a wide variety of architectures. As an example, four groups of banks, resulting in s single pass/fail bit each, may be read out on 4 SRWD lines, with the addition of more buffers controlling the data paths. Further, one skilled in the art will recognize that, for some embodiments, test compression logic may be moved physically closer to the banks, allowing compressed test data to be transferred, to similar effect on YRWD lines.

### CONCLUSION

Compared to conventional compressed test modes, embodiments of the present invention may provide improved throughput by utilizing parallel access to multiple banks.

While the foregoing is directed to embodiments of the present invention, other and further embodiments of the invention may be devised without departing from the basic scope thereof, and the scope thereof is determined by the claims that follow.

What is claimed is:

1. A method of testing a memory device, comprising:
reading a plurality of bits from multiple banks of the memory device in parallel;
generating, from the plurality of bits read from each bank, a reduced number of one or more compressed test data bits;
combining the compressed test data bits from each bank to form a reduced number of one or more combined test data bits;
routing the combined test data bits to one or more data lines shared between the multiple banks; and
providing the combined test data bits as output on one or more data pins of the memory device.

2. The method of claim 1, wherein generating a reduced number of one or more compressed data bits comprises:
generating, from the plurality of bits read from each bank, a single pass/fail bit for each bank indicating whether the corresponding plurality of bits matches predefined test data.

3. The method of claim 2, wherein combining the compressed test data bits from each bank to form a reduced number of one or more combined test data bits comprises:
generating a single combined bit from the single pass/fail bits for each bank.

4. The method of claim 1, wherein generating the reduced number of compressed test data bits comprises generating a single bit based on a burst of data bits read from a memory bank.

5. The method of claim 1, wherein generating the reduced number of compressed data bits comprises comparing sets of the plurality of data bits to one or more known test data patterns previously written to the memory banks.

6. The method of claim 1, wherein the first bank is selected from a first group of four or more banks and the second bank is selected from a second group of four or more banks.

7. A memory device, comprising:
a plurality of banks of memory cells;
one or more test logic circuits, each configured to generate, from a plurality of bits read from a bank, a reduced number of one or more compressed test data bits; and
logic configured to read a plurality of bits from multiple banks of the memory device in parallel, combine a plurality of compressed test data bits received from the test logic circuits to form a reduced number of one or more combined test data bits, route the combined test data bits to one or more data lines shared between the multiple banks, and provide the combined test data bits as output on one or more data pins of the memory device.

8. The memory device of claim 7, wherein:
the plurality of banks comprises at least two groups of memory banks, with banks in each group sharing a first common set of data lines and the groups sharing a second set of common data lines; and
the one or more test logic circuits comprise a test logic circuit for each group of memory banks.

9. The memory device of claim 8, wherein the test logic for each group of memory banks generates a reduced number of test data bits from data received on the first common set of data lines and routes the reduced number of compressed data bits to the second set of common data lines.

10. The memory device of claim 7, wherein the plurality of banks comprises more than four banks.

11. The memory device of claim 7, wherein each test logic circuit is configured to generate a single pass/fail bit indicating whether a plurality of bits read from a corresponding bank matches data in a predefined test data register.

12. A dynamic random access memory (DRAM) device, comprising:
at least two groups of memory cell banks, wherein a first set of common data lines is shared between banks in each group and a second set of common data lines is shared between the groups;
one or more test logic circuits, each configured to generate, from a plurality of bits read from a bank, a single pass/fail bit indicating whether the corresponding plurality of bits matches predefined test data; and
logic configured to read a plurality of bits from multiple banks of the memory device in parallel, combine a plurality of pass/fail bits received from the test logic circuits to form a combined pass/fail bit, route the combined test data bits to one or more data lines shared between the multiple banks, and provide the combined test data bits as output on one or more data pins of the memory device.

13. The memory device of claim 12, wherein:
the plurality of banks comprises at least two groups of memory banks, with banks in each group sharing a first common set of data lines and the groups sharing a second set of common data lines; and
the one or more test logic circuits comprise a test logic circuit for each group of memory banks.

14. The memory device of claim 13, wherein the test logic for each group of memory banks generates a reduced number of test data bits from data received on the first common set of data lines and routes the reduced number of compressed data bits to the second set of common data lines.

15. The memory device of claim 12, wherein the plurality of banks comprises more than four banks.

16. A system, comprising:
a tester; and
one or more memory devices, each comprising a plurality of banks of memory cells and logic configured to, when the memory device has been placed in a test mode by the tester, read a plurality of bits from multiple banks of the memory device in parallel, generate, from the plurality of bits read from each bank, a reduced number of one or more compressed test data bits, combine the compressed test data bits from each bank to form a reduced number of one or more combined test data bits, route the combined test data bits to one or more data lines shared between the multiple banks, and provide the combined test data bits to the tester as output on one or more data pins of the memory device.

17. The system of claim 16, wherein the logic is configured to generate a reduced number of one or more compressed data bits by generating, from the plurality of bits read from each bank, a single pass/fail bit for each bank indicating whether the corresponding plurality of bits matches predefined test data.

18. The system of claim 17, wherein the multiple banks comprise a first bank selected from a first group of four or more banks and a second bank selected from a second group of four or more banks.

19. The system of claim 17, wherein the tester is configured to place the one or more memory devices in the test mode via a mode register set (MRS) command.

20. A memory device, comprising:
multiple banks of memory cells;
test means for generating, from a plurality of bits read from a bank, a reduced number of one or more compressed test data bits; and
control means configured to, when the device is in a test mode, read a plurality of bits from multiple banks of the memory device in parallel, combine a plurality of compressed test data bits generated by the test means to form a reduced number of one or more combined test data bits, route the combined test data bits to one or more data lines shared between the multiple banks, and provide the combined test data bits as output on one or more data pins of the memory device.

21. The memory device of claim 20, wherein:
the plurality of banks comprises at least two groups of memory banks, with banks in each group sharing a first common set of data lines and the groups sharing a second set of common data lines; and
separate test means are provided for each group of memory banks.

22. The memory device of claim 21, wherein the test means for each group of banks generates a reduced number of test data bits from data received on the first common set of data lines and routes the reduced number of compressed data bits to the second set of common data lines.

23. The memory device of claim 21, wherein test means for each group of banks is configured to generate a single pass/fail bit indicative of whether a plurality of bits read from a corresponding bank matches predefined test data.

24. The memory device of claim 20, wherein the plurality of banks comprises more than four banks.
